(19) United States
(12) Patent Application Publication
(10) Pub. No.: US 2005/0110038 A1
(43) Pub. Date: May 26, 2005

(54) High voltage semiconductor device having current localization region

(76) Inventors: Roman J. Hamerski, Olathe, KS (US); Walter R. Buchanan, Olathe, KS (US)

Correspondence Address: BLACKWELL SANDERS PEPER MARTIN LLP, 4801 Main Street, Suite 1000, KANSAS CITY, MO, 64112, US

(21) Appl. No.: 10/718,827

(22) Filed: Nov. 21, 2003

(51) Int. Cl. H01L 29/861; H01L 29/88

(52) U.S. Cl. 257/104; 438/309

(57) ABSTRACT

A high voltage semiconductor device, having a first layer of semiconductor material, a current localization region, a second layer of semiconductor material and a third layer of semiconductor material, is utilized to improve the electrical characteristics of the device by reducing the thickness of the second layer. The reduction of the thickness of the second layer provides for a reduction in edge failures as compared to prior art. The reduced thickness of the second layer also provides for a reduction in forward voltage drop across the device. The reduced thickness of the second layer also results in a reduced dynamic impedance of the device.

### FIELD OF THE INVENTION

This invention relates to semiconductor devices, and, more particularly, to semiconductor devices and methods of manufacturing semiconductor devices with improved protection from edge failures, reduced forward voltage drop, and reduced dynamic impedance.

### BACKGROUND OF THE INVENTION

Semiconductor devices are commonly formed by subjecting wafers of semiconductor material to several processing steps in which various layers and coatings are applied to the wafer. After the desired layers have been applied to the wafer, it is a common practice, particularly in the power semi-conductor business, that moats are etched in the surface of the wafer to separate and define the individual devices. Etching the moats is also one of the steps in forming the edge terminations of the devices. Failure in semiconductor devices commonly occurs at the edge terminations of the devices where the moats are etched. Such failures are caused by electric field magnitudes that are too large for the edges of the devices. To minimize these failures, edge termination configurations and methods of forming the edge terminations have been developed. These configurations and methods have not satisfactorily resolved edge termination failures.

In specific semiconductor applications, such as PN diodes, other concerns arise as well as the edge termination failures. In a forward current flow, from the P layer to the N layer, current flows through the PN diode after a minimum voltage is reached. This voltage can be, for example, 0.7 volts. The voltage drop will continue to increase as the forward current increases. Traditional PN semiconductor devices experience this high forward voltage drop. In other words, the voltage drop across the PN diode during the current transmission period of the diode's operation is undesirably high.

### BRIEF SUMMARY OF THE INVENTION

There is, therefore, provided in the practice of the invention a novel semiconductor device, which provides for an improved protection from edge failures and a reduced forward voltage drop. The semiconductor device broadly includes a first layer of semiconductor material of a first layer conductivity type. A current localization region is adjacent the first side of the first layer. The device also includes a second layer of semiconductor material of a second layer conductivity type.

In one embodiment, a third layer of semiconductor material of a third layer conductivity type is adjacent the second side of the second layer. Further, the first layer of semiconductor material is a low resistivity semiconductor material having an N-type dopant. The current localization region is positioned so that a central portion of the second layer of semiconductor material is thinner than the sides of the second layer of semiconductor material. The second layer of semiconductor material is a high resistivity semiconductor material of the same conductivity type as the first layer of semiconductor material, and the third layer of semiconductor material is a P+ material in order to create a PN junction. Thus, a distance in a central portion of the device from the current localization region to the third layer of semiconductor material is less than a distance from the first layer to the third layer at the edge of the device. It is further contemplated in the practice of a preferred embodiment of the invention that the first layer conductivity type and the second layer conductivity type are the same conductivity type.

In another aspect of the invention, the device is formed by a method which includes forming a first layer of semiconductor material; implanting ions in the first layer of semiconductor material; forming a second layer of semiconductor material; and heating the device to diffuse the implanted ions. The method of fabricating a semiconductor device can also include forming a third layer of semiconductor material.

Accordingly, it is an object of the present invention to provide an improved high voltage device having a modified layer height for providing an improved protection from edge failures and a reduced forward voltage drop.

### BRIEF DESCRIPTION OF THE DRAWINGS

These and other inventive features, advantages, and objects will appear from the following Detailed Description when considered in connection with the accompanying drawings wherein:

FIG. 1 is an enlarged, cross-sectional view of a high voltage device having improved characteristics according to the present invention;

FIG. 2 is an enlarged, cross-sectional view of an alternative embodiment to the device shown in FIG. 1, showing the device having an etching mask applied to one surface and after the surface has been etched; and

FIG. 3 is a view similar to FIG. 2 showing the device after the mask has been removed and after the wafer has undergone diffusion.

For the purpose of clarity in illustrating the characteristics of the present invention, accurate proportional relationships of the elements thereof have not been maintained in the Figures. Further, the sizes of certain small devices and elements thereof have been exaggerated.

### DETAILED DESCRIPTION

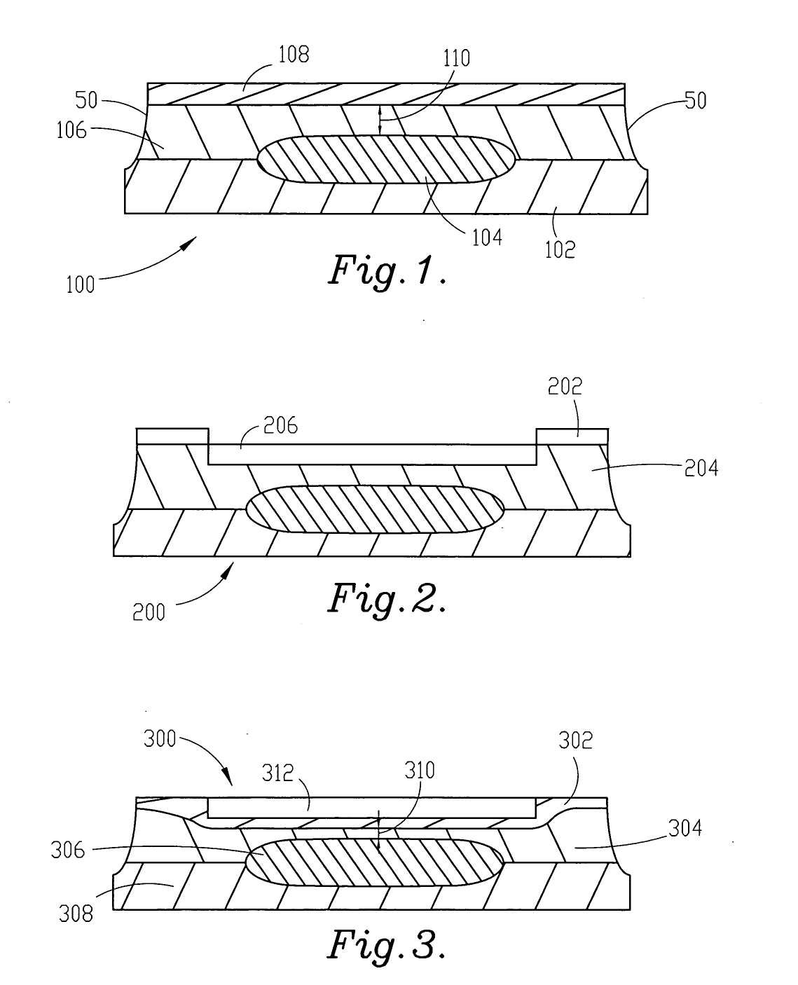

Referring to the drawings in greater detail, FIG. 1 shows a high voltage device 100 constructed in accordance with a preferred embodiment of the present invention. The high voltage device 100 broadly includes a first layer 102 of semiconductor material, a current localization region 104, and a second layer 106 of semiconductor material. The current localization region 104 is positioned so that a central portion of the second layer 106 of semiconductor material is thinner than the sides of the second layer 106 of semiconductor material. Therefore, the second layer 106 essentially has a varied thickness. This structure provides for an improved protection from edge failures and a reduced forward voltage drop. A preferred embodiment also includes a third layer 108 of semiconductor material.

The first layer 102 of semiconductor material is of a first layer conductivity type, the first layer of semiconductor material has a first upper side and a second lower side. Upper and lower are used only to describe the frame of reference in the drawing and are not intended to be limitations. In a preferred embodiment, the first layer 102 includes a low resistivity semiconductor material having an N type dopant. The first layer 102 is preferably N+. The semiconductor material can be silicon, germanium, or any semiconductor material such as gallium arsenide with appropriate changes are made to the dopant material depending on the semiconductor material selected. An N-type dopant can be selected from many different chemicals, including phosphorous, arsenic and antimony depending on the semi-conductor material selected.

The current localization region is positioned in the first layer of semiconductor material and in the second layer of semiconductor material and adjacent to the first/upper side of the first layer of semiconductor material, the current localization region extend beyond the first upper side of the first layer of semiconductor material. The current localization region 104 extends beyond the N+ low resistivity layer such that a distance in a central portion of the device 100 from the current localization region 104 to the third layer 108 of semiconductor material is less than a distance from the first layer 102 of semiconductor material to the third layer 108 of semiconductor material at the edge of the device 100. A central portion of the first side of the first layer 102 is enclosed by the current localization region 104.

In one embodiment, the current localization region 104 is created by placing a dopant in the top portion of the first layer 102. To summarize, this is accomplished by introducing a dopant through ion implantation, followed by a diffusion process. The implant dopant is preferably the same type of dopant at a higher concentration resulting in a region of N++ before diffusion. The N++ region is located in the upper portion of the first layer adjacent the upper side. After ion implantation, the second layer 106 of semiconductor material is formed. The second layer 106 of semiconductor material has a second layer conductivity type, the second layer 106 of semiconductor material having first and second sides. The first layer conductivity type and the second layer conductivity type are preferably the same conductivity type. The first and second layer conductivity types are preferably N-type. In one embodiment, the second layer 106 is a high resistivity material of the same conductivity type as the first layer 102. The second layer 106 can be an epitaxial deposition of a high resistivity type such as N−. Therefore, the second layer 106 can be of the same dopant as the first layer 102 yet very lightly doped. The second layer 106 is grown adjacent to the first/upper side of the first layer 102 covering or burying the N++ region. The high voltage device 100 is heated to diffuse the implanted ions into the second layer 106 resulting in the configuration shown in FIG. 1. The high concentration of ions results in a number of them diffusing into the second layer to complete the current localization region 104. The third layer 108 of semiconductor material is of a third layer conductivity type, and the third layer 108 of semiconductor material also has first and second sides, wherein the second side of the third layer is adjacent the first side of the second layer 106 of semiconductor material. In one embodiment, the third layer 108 of semiconductor material is a P+ material which creates a PN junction.

Another method to create the current localization region 104 includes using a dopant that diffuses at a faster rate than the dopant of the surrounding material. In one embodiment, this current localization region dopant is phosphorus, which is smaller in size and thus diffuses faster than arsenic which is the first layer dopant. These dopants are used when the first and second layers are N type. If the first and second layers are P type, the current localization region dopant is Cesium (Cs-135) and the first layer dopant is Boron in one embodiment. After the ion implantation, the second layer 106 is formed. The high voltage device 100 is heated to diffuse the implanted ions into the second layer 106. The faster moving dopant diffuses into the second layer faster than the surrounding dopant to complete the current localization region 104, so that the distance 110 from the current localization region is smaller than the distance from the first layer 102 to the third layer 108 at the edge of the device. The range of temperature for diffusion may be the same or different for both embodiments. Therefore, the device is preferably fabricated by forming a low resistivity first layer of semiconductor material; introducing a high concentration of dopant into the low resistivity layer at a predetermined location; forming a high resistivity second layer of semiconductor material; and heating to diffuse the dopant to form a current localization region. The method of fabricating a semiconductor device also includes forming a third layer of semiconductor material. A preferred embodiment includes forming a first layer of semiconductor material; implanting ions in the first layer of semiconductor material; forming a second layer of semiconductor material; and heating the device to diffuse the implanted ions. Thus, it is possible for the first layer to be either a low resistivity or high resistivity.

In an alternate embodiment of the invention illustrated in FIGS. 2 and 3, a photo-resist mask 202, shown in FIG. 2, is removably applied to the opposing surface of a second layer 204. Exposed portions of the opposing surface of the second layer 204 are then directly etched to a predetermined depth. This forms a well 206 in each exposed portion, and each well 206 corresponds to an individual semiconductor device. The depth is predetermined in that it is selected prior to etching. Upon removal of the mask 202, a third layer 302, shown in FIG. 3, is diffused into the upper side of a second layer 304. In a preferred embodiment, the dopant is a P-type dopant. Alternatively, the third layer 302 can be epitaxially grown.

In FIG. 3, a current localization region 306 extends beyond the N+ low resistivity layer 308 such that a distance 310 in a central portion of the device 300 from the current localization region 306 to the third layer 302 of semiconductor material is less than a distance from a first layer 308 of semiconductor material to the third layer 302 of semiconductor material at the edge of device 300. Described differently, a central portion of the first side of the first layer 308 is enclosed by the current localization region 306. A thickness 310 of the second layer 304 in this embodiment can be thinner than a thickness 110 of the second layer 106 in the embodiment shown in FIG. 1.

As discussed above, the current localization region 306 is preferably created by such methods as an ion implantation into the first layer 308, followed by a diffusion process. The implant can be the same type of dopant in a higher concentration resulting in a region of N++. The dopant can be, for example, phosphorous. After the ion implantation, the second layer 304 of semiconductor material is formed. The second layer 304 is preferably a high resistivity material of the same conductivity type as the first layer 308. The second layer 304 can be an epitaxial deposition of a high resistivity type such as N−. Therefore, the second layer 304 can be of the same dopant as the first layer 308 yet very lightly doped. The second layer 304 can be grown adjacent to one surface of the first layer 308. The high voltage device 300 can be heated to diffuse the implanted ions into the second layer as shown. The third layer 302 of semiconductor material of a third conductivity type is adjacent the second side of the second layer 304. In one embodiment, the third layer 302 is P+ material in order to create a PN junction. A well 312 corresponds to an individual semiconductor device.

Another method to create the current localization region 306 can include using ion implantation with an implant of a dopant that diffuses at a faster rate than the dopant of the surrounding material. This dopant may be, for example, phosphorus, which is smaller in size and thus diffuses faster than arsenic. After ion implantation, the second layer 304 is formed. The high voltage device 300 can be heated to diffuse the implanted ions into the second layer 304. The range of temperature for diffusion may be the same or different for both embodiments.

The high voltage devices 100, 300 according to the present invention provide shorter more direct paths, or thicknesses 110, 310 of the second layer for the current to progress through the devices 100, 300 therefore reducing edge failures as compared to prior art. The reduced thicknesses 110, 310 of the second layer also provides for a reduction in forward voltage drop across the devices 100, 300 which can be diodes. The reduced thicknesses 110, 310 of the second layer also result in a reduced dynamic impedance of the devices. The final devices will also have edge terminations formed by moats 50.

Thus, a high voltage device is disclosed which utilizes a current localization region to reduce the thickness of the second layer thereby improving electrical characteristics. While preferred embodiments and particular applications of this invention have been shown and described, it is apparent to those skilled in the art that many other modifications and applications of this invention are possible without departing from the inventive concepts herein. For example, the layers are referred to as N or P types, but might be other types, such as the reversal of the types N and P. It is, therefore, to be understood that, within the scope of the appended claims, this invention may be practiced otherwise than as specifically described, and the invention is not to be restricted except in the spirit of the appended claims. Though some of the features of the invention may be claimed in dependency, each feature has merit if used independently.

1. A semiconductor device comprising:
a first layer of semiconductor material of a first layer conductivity type, the first layer of semiconductor material having first and second sides;
a second layer of semiconductor material of a second layer conductivity type, the second layer of semiconductor material having first and second sides with the first side of the first layer adjacent the second side of the second layer; and
a current localization region positioned in the first layer of semiconductor material and in the second layer of semiconductor material and adjacent to the first side of the first layer of semiconductor material, the current localization region extending beyond the first side of the first layer of semiconductor material into the second layer.

2. The semiconductor device as claimed in claim 1 wherein the first layer conductivity type and the second layer conductivity type are a same conductivity type.

3. The semiconductor device as claimed in claim 2 wherein the same conductivity type is N type.

4. The semiconductor device as claimed in claim 1 wherein the second layer of semiconductor varies in width, such that a central portion of the second layer of semiconductor is thinner than sides of the second layer of semiconductor.

5. The semiconductor device as claimed in claim 1 wherein a distance in a central portion of the device from the current localization region to the third layer of semiconductor material is less than a distance from the first layer of semiconductor material to the third layer of semiconductor material at the edge of the device.

6. The semiconductor device as claimed in claim 1 further including a third layer of semiconductor material of a third layer conductivity type, the third layer of semiconductor material having first and second sides, wherein the first side is adjacent the second side of the second layer of semiconductor material.

7. The semiconductor device as claimed in claim 1 further including a first layer dopant and a current localization region dopant wherein the current localization region dopant diffuses faster than the first layer dopant.

8. The semiconductor device as claimed in claim 7 wherein the first layer dopant comprises arsenic, and the current localization dopant comprises phosphorus.

9. The semiconductor device as claimed in claim 7 wherein the first layer dopant comprises boron and Cesium (CS-135), and the current localization dopant comprises phosphorus.

10. The semiconductor device as claimed in claim 1 wherein the current localization dopant is substantially the same as the first layer dopant.

11. A method of fabricating a semiconductor device, the method comprising:
forming a low resistivity first layer of semiconductor material;
introducing a dopant into the low resistivity layer at a predetermined location;
forming a high resistivity second layer of semiconductor material; and
heating to diffuse the dopant to form a current localization region.

12. The method of fabricating a semiconductor device as claimed in claim 11 wherein the dopant is phosphorus.

13. The method of fabricating a semiconductor device as claimed in claim 11 wherein the first layer of semiconductor material is N+.

14. The method of fabricating a semiconductor device as claimed in claim 11 wherein the second layer of semiconductor material is N−.

15. The method of fabricating a semiconductor device as claimed in claim 11 wherein the third layer of semiconductor material is P+.

16. The method of fabricating a semiconductor device as claimed in claim 11 wherein introducing a dopant is performed through ion implantation.

17. The method of fabricating a semiconductor device as claimed in claim 11 further including forming a third layer of semiconductor material.

18. A method of fabricating a semiconductor device, the method comprising:
forming a first layer of semiconductor material;
thereafter, introducing ions in the first layer of semiconductor material;
thereafter, forming a second layer of semiconductor material on the first layer; and
thereafter, heating the device to diffuse the implanted ions.

19. The method of fabricating a semiconductor device as claimed in claim 18 further including, forming a third layer of semiconductor material.

20. A method of fabricating a semiconductor device, the method comprising:
forming a low resistivity first layer of semiconductor material and having a first layer dopant;
introducing a current localization dopant into the low resistivity layer at a predetermined location, the current localization dopant having a faster diffusion rate than the first layer dopant;
forming a high resistivity second layer of semiconductor material; and
heating to diffuse the dopant to form a current localization region.
